(19) United States
(12) Patent Application Publication
(10) Pub. No.: US 2025/0351297 A1
(43) Pub. Date: Nov. 13, 2025

(54) HEAT DISSIPATION ASSEMBLY FOR ELECTRONIC EQUIPMENT

(71) Applicant: ASIA VITAL COMPONENTS CO., LTD., NEW TAIPEI CITY (TW)

(72) Inventor: CHING HANG SHEN, NEW TAIPEI CITY (TW)

(21) Appl. No.: 18/777,890

(22) Filed: Jul. 19, 2024

(30) Foreign Application Priority Data
May 8, 2024 (TW) 113116999

(51) Int. Cl. H05K 7/20

(52) U.S. Cl. CPC H05K 7/20272; H05K 7/20263; H05K 7/20927

(57) ABSTRACT

A heat dissipation assembly for electronic equipment includes an internal circulation heat dissipation assembly consisting of at least one water block mounted on a power heat source on a motherboard of the electronic equipment and at least one water cooling radiator connected to the water block via pipes; and an external forced cooling assembly connected to the internal circulation heat dissipation assembly via pipes. A working fluid in the water block quickly absorbs heat produced by the power heat source, and the working fluid with absorbed heat undergoes a front stage of heat dissipation in the water cooling radiator and a rear stage of forced heat dissipation in the external forced cooling assembly. By cooling the working fluid in multiple stages, the working fluid can have upgraded cooling efficiency to prevent heat from depositing in the power heat source and the system unit of the electronic equipment.

### FIELD OF THE INVENTION

The present invention relates to a heat dissipation assembly for electronic equipment, and more particularly, to a heat dissipation assembly capable of upgrading heat dissipation performance and preventing heat deposition in a power heat source or a system unit of the electronic equipment.

### BACKGROUND OF THE INVENTION

With the advanced integrated circuit technology, a plurality of system units, including servers and chassis, of electronic equipment can be now integrated in one cabinet to effectively save the working space to be occupied by the system units or cabinets when construct the electronic equipment. However, every cabinet and every system unit have relatively limited internal space, which has a direct influence on the efficiency of dissipating the working heat produced by the power heat source in the electronic equipment.

In the conventional system unit, air cooling or water cooling circulation system is used to dissipate the heat produced by the system unit during operation thereof. Regarding the air cooling system, heat radiators, heat pipes or radiation fins are used to carry the working heat produced by the power heat source away from the internal space of the chassis, and one or more fans are used to produce airflows to push the hot air out of the chassis while pulling external cold air into the chassis to form an air cooling circulation system. On the other hand, in the water cooling system, at least one water block is correspondingly mounted in the chassis at a position having a power heat source; and the water block is then connected via pipes to an external forced cooling device provided outside the chassis or assembled to a cabinet, so that a working fluid circulates through the water block to carry away heat and cool down the power heat source. Recently, an adequate amount of fans can also be provided on a lateral side of the chassis to suck in external cold air and expel internal hot air to form convection or heat transfer in the internal space of the chassis as a way to assist in the water cooling. For instance, Taiwan Patent Pub. No. 202415203 (hereinafter referred to as the prior case) discloses the use of a water block in direct contact with the power heat source, so that working heat produced by the power heat source is carried away by a working fluid to an external forced cooling device, at where the working fluid is cooled through heat exchange. Working heat produced by other heat source in the chassis is expelled from the chassis using fans to thereby cool the internal space of the chassis.

The conventional simple air cooling heat dissipation system uses air as a cooling medium, which exchanges heat with cold air in external environment to achieve the purpose of heat dissipation. However, in view that air cooling has relatively low heat transfer efficiency, there has developed a three-dimensional thermal module consisting of heat pipes and a heat sink or a vapor chamber in an attempt to provide upgraded heat dissipation effect. Since most system units have limited internal space for heat dissipation, the use of the three-dimensional thermal module does not effectively provide largely upgraded critical heat dissipation efficiency. Therefore, the conventional air cooling has reached its upper limit in capacity and could not satisfy the working environment that requires higher power heat source to perform necessary operations. To provide the integrated electronic equipment, such as server cabinets and communication chassis, with even better heat dissipation efficiency, as shown in FIGS. 1 and 2, some examples of the currently available heat dissipation systems for cooling the power heat source 14 on a motherboard 5 in the electronic equipment include a simple water cooling circulation system, and a composite cooling circulation system combining an air cooling system with a water cooling system, as the above-described prior case, or combining a water cooling system with another water cooling system. Compared to the conventional air cooling module, the water cooling module in the above composite cooling system further includes a water block 10, a coolant distribution unit (CDU) 11, and an external forced cooling assembly such as an air heat exchange cooler 12 or a liquid heat exchange cooler 13.

Generally, fans 15 for air cooling are provided at an inner front side, an inner rear side, an outer front side or an outer rear side of a system unit of the electronic equipment to forcefully suck in or expel out air, so as to expel hot air in the server chassis out of the electronic equipment. That is, in the case of air cooling, fans are used to enhance convection of hot air and cold air inside and outside the electronic equipment, respectively.

Conventionally, the fans provided in the electronic equipment for air cooling can only provide convection and circulation of airflow inside and outside the electronic equipment and is not helpful in cooling down the working fluid in the water cooling system. When the working fluid in the water block 10 absorbs working heat produced by the power heat source in the electronic equipment, the working fluid is heated and would first flow to the coolant distribution unit (CDU) 11 and then flow to the air heat exchange cooler 12, at where heat convection occurs with the aid of a heat sink 20 and a fan 121 to cool down the working fluid in the air heat exchange cooler 12. The cooled working fluid flows through the CDU 11 again and goes back to the electronic equipment to circulate and cool the power heat source 14.

In the water cooling circulation system, the water block 10 is mounted at a position corresponding to the power heat source 14 in the electronic equipment; the water block 10 is then connected via pipes 101 to the external forced cooling assembly outside the electronic equipment. The working fluid for cooling circulates through the water cooling circulation system to exchange heat with the power heat source 14 and carry the heat produced by the power heat source 14 away from the electronic equipment. Thereafter, the working fluid absorbed the heat produced by the power heat source 14 is cooled down by an air heat exchanger cooler 12 or a liquid heat exchanger cooler 13 and then flows through the CDU 11 and pumped into the electronic equipment again to absorb the heat produced by the power heat source 14 and starts a new cycle of the circulation cooling operation.

Presently, a problem encountered by the existing heat dissipation assembly is that the number of power heat sources 14 in the electronic equipment for data processing is largely increased, the highly heated working fluid circulating through and flowing out of the electronic equipment in normal procedures is not sufficiently cooled down to a temperature equivalent or lower than a desired working temperature before it flows back to the electronic equipment to circulate and cool the power heat source. When the insufficiently cooled working fluid continuously flows back to the electronic equipment at an undesirable high temperature, a temperature difference or hot level difference between the working fluid and the power heat source is relatively small, which leads to largely reduced heat dissipation efficiency and insufficiently cooled power heat source. Under this condition, the heat produced by the power heat source would accumulate constantly to finally result in crash of the electronic equipment or burn out of the power heat source due to overheat. The above problem is not improved even though the composite cooling circulation system as described in the prior case has been developed.

It is therefore an important issue for those skilled in the art to overcome the problem of insufficiently cooled working fluid in the conventional water cooling system.

In the matter of fact, water cooling is the currently available pretty effective heat dissipation solution, but it requires the working fluid in the water block to absorb the heat produced by the power heat source and then flows while carrying the absorbed heat to the external forced cooling assembly outside the chassis to be cooled to an expected working temperature before flows back to the chassis to cool down the power heat source through heat exchange. Although the present chassis heat dissipation solution has already included both air cooling and water cooling, the air cooling can only provide convection of the hot air and the cold air inside and outside the chassis, respectively, without providing multiplied cooling effect on the heat produced directly by the power heat source. On the other hand, while the water cooling can cool down the power heat source directly through heat exchange, it requires additional forced cooling assembly provided inside or outside the system unit to enhance the circulation cooling efficiency thereof when the heat produced by the power heat source increases, so that the chassis can be sufficiently cooled.

Although the existing heat dissipation manners will suffice the present demands for dissipating heat from the chassis, the working power required by all the power heat sources in one single chassis increases constantly, and the number of chassis in one single system unit also increases day by day. It is apparently the problem of insufficient heat dissipation efficiency will come in near future if the heat dissipation systems is improved only by adding more air cooling fans and external forced cooling devices. Further, the increase of air cooling fans and external forced cooling devices would in turn increase the cost of heat dissipation operation and is therefore not an ideal solution.

It is therefore tried by the electronic industry to integrate air cooling with water cooling in an improved manner, in order to get multiplied heat dissipation effect and avoid the system unit or the whole cabinet of the electronic equipment from insufficient heat dissipation.

### SUMMARY OF THE INVENTION

A primary object of the present invention is to effectively solve the problems in the conventional cooling systems by providing a heat dissipation assembly for electronic equipment to upgrade the heat dissipation performance of a high-power system unit.

To achieve the above and other objects, the heat dissipation assembly for electronic equipment according to the present invention includes an internal circulation heat dissipation assembly and an external forced cooling assembly. The internal circulation heat dissipation assembly includes at least one water block mounted on a power heat source on a motherboard and at least one water cooling radiator connected to the water block via pipes. The internal circulation heat dissipation assembly is further connected to the external forced cooling assembly via pipes. A working fluid in the water block quickly absorbs working heat produced by the power heat source and circulates through the water cooling radiator, at where the working fluid is subjected to a front stage heat dissipation and then further circulates through the external forced cooling assembly and undergoes a rear stage forced heat dissipation. Therefore, the heat dissipation assembly of the present invention forms a composite heat dissipation cooling system including at least two stages of heat dissipation to provide largely upgraded overall heat dissipation performance.

In the above-described heat dissipation assembly, the water cooling radiator is featured by small volume but large heat dissipation area, and can be used in a narrow space between the chassis and the motherboard of the electronic equipment to provide at least one preliminary large-scale front stage heat dissipation operation before a rear stage forced heat dissipation. Therefore, the working fluid can provide higher cooling efficiency, enabling the working fluid to exactly drop to a desired low working temperature when it circulates back to the water block on the motherboard and avoiding insufficient heat dissipation at the power heat source or in the chassis to cause the problem of heat deposition.

According to the heat dissipation assembly of the present invention, enhanced pushing fans are further provided in the chassis at or between a middle section and a rear section, in order to increase the convection rate of the air inside the system unit and the air outside the system unit of the electronic equipment. Thus, the large amount of heat dissipated from the water cooling radiator can be effectively expelled from the chassis to avoid heat deposition in the chassis.

### BRIEF DESCRIPTION OF THE DRAWINGS

FIG. 1 is a conceptual view of a conventional composite heat dissipation circulation system that combines air cooling with water cooling;

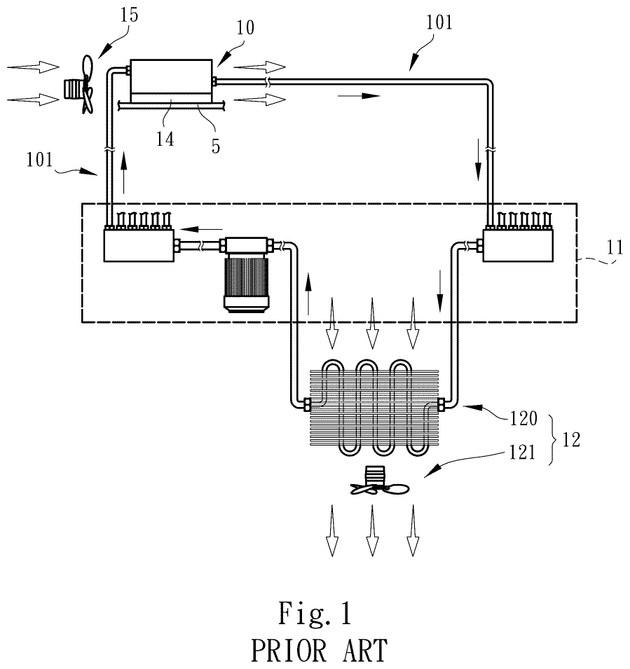

FIG. 2 is a conceptual view of another conventional composite heat dissipation circulation system that combines air cooling with water cooling;

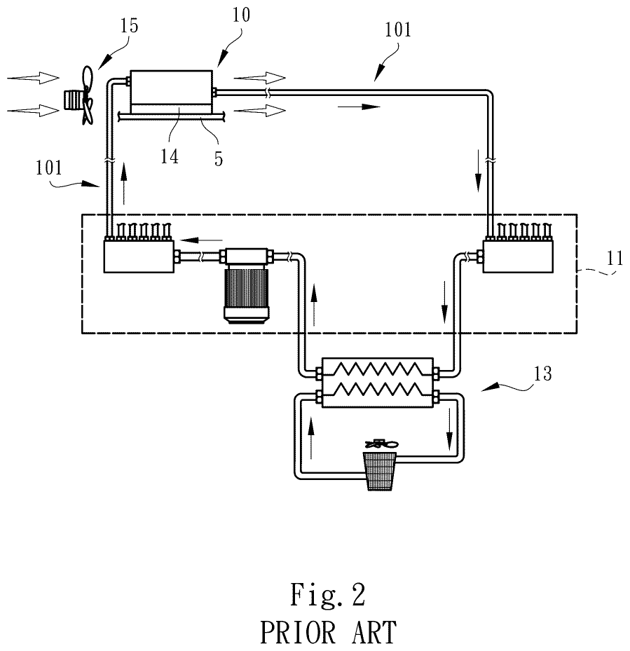

FIG. 3 shows a heat dissipation assembly according to an embodiment of the present invention;

FIG. 4 is a top view showing an embodiment of the heat dissipation assembly of the present invention being used on electronic equipment that has a plurality of heat sources provided on one single motherboard;

FIG. 5 is a side view of the embodiment of the present invention shown in FIG. 4;

FIG. 6 is a perspective view showing an embodiment of the heat dissipation assembly of the present invention being used on electronic equipment that has one single heat source provided on one single motherboard;

FIG. 7 is a top view of the embodiment of the present invention shown in FIG. 6;

FIG. 8 is a side view of the embodiment of the present invention shown in FIG. 6; and

FIG. 9 is another top view of the embodiment of the present invention shown in FIG. 6.

### DETAILED DESCRIPTION OF THE PREFERRED EMBODIMENTS

The above objects and the structural and functional features of the present invention will now be described with some preferred embodiments thereof by referring to the accompanying drawings.

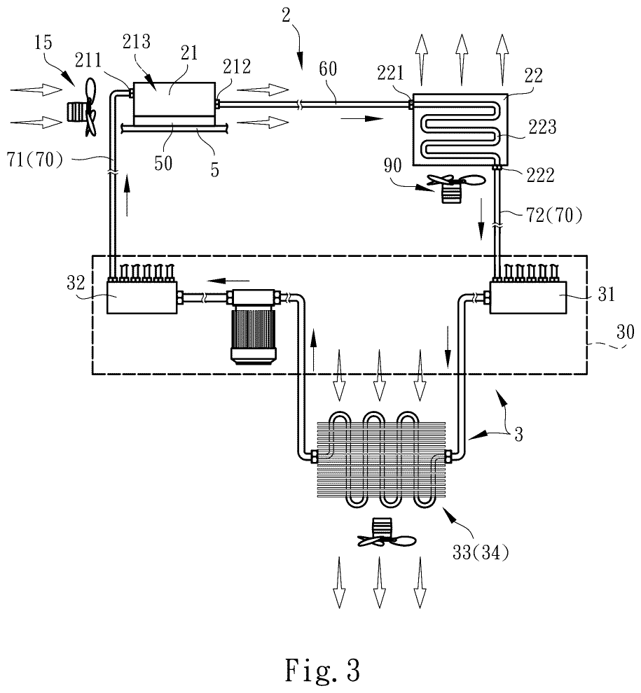

Please refer to FIG. 3, which shows a heat dissipation assembly according to an operable embodiment of the present invention. As shown, the heat dissipation assembly of the present invention includes an internal circulation heat dissipation assembly 2 and an external forced cooling assembly 3. The internal circulation heat dissipation assembly 2 consists of at least one water block 21 assembled to a power heat source 50 on a motherboard 5 in a piece of electronic equipment and at least one water cooling radiator 22 connected via pipes to the water block 21.

The water block 21 is provided corresponding to and in contact with the power heat source 50 to carry away working heat produced by the power heat source 50. The water block 21 includes a water inlet 211 and a water outlet 212, and internally defines at least one heat exchange space 213. The water outlet 212 is further connected to the water cooling radiator 22 or another water block 21.

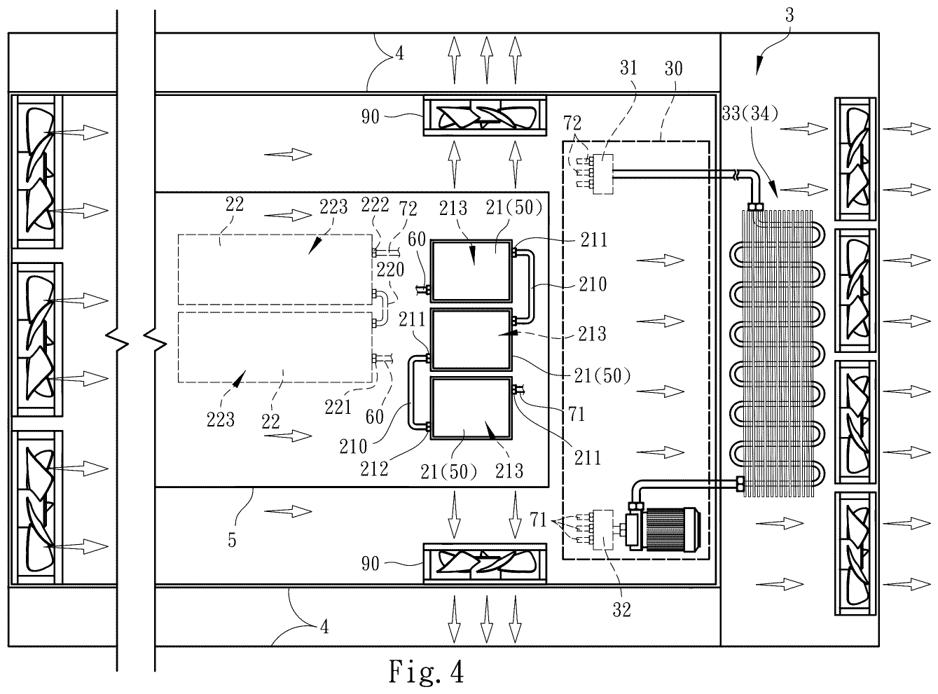

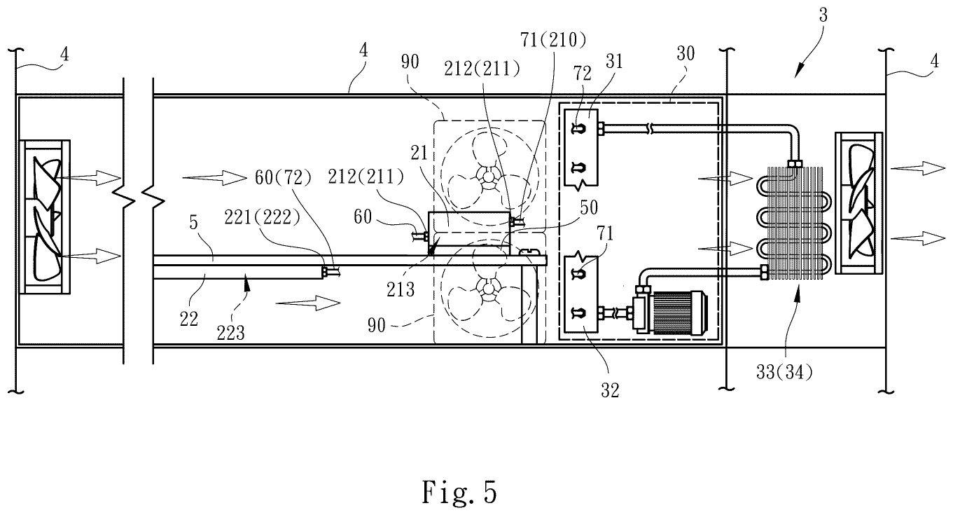

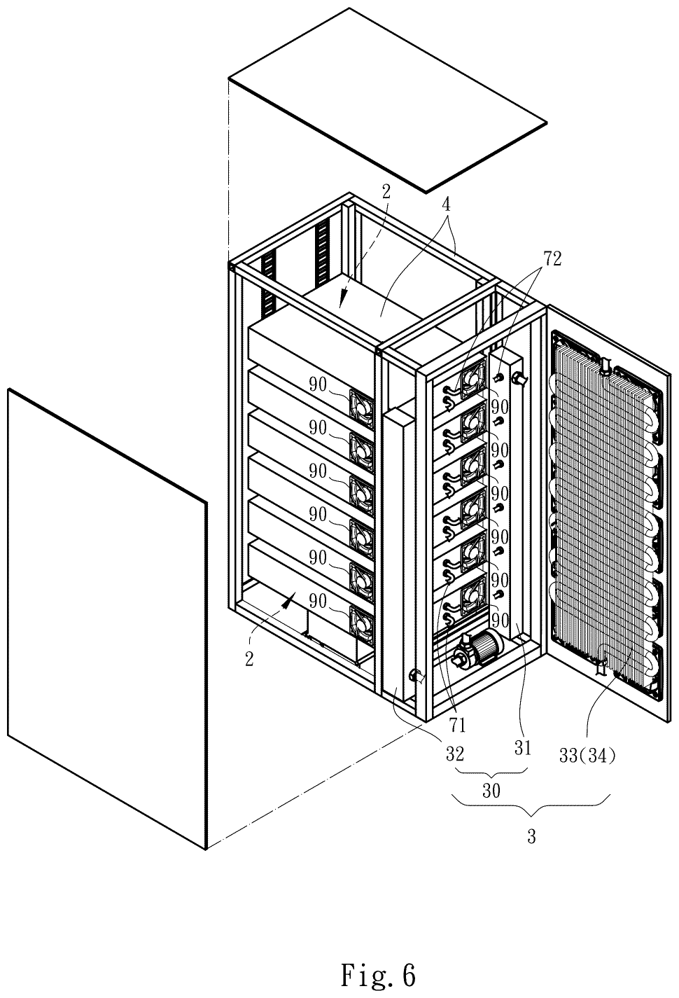

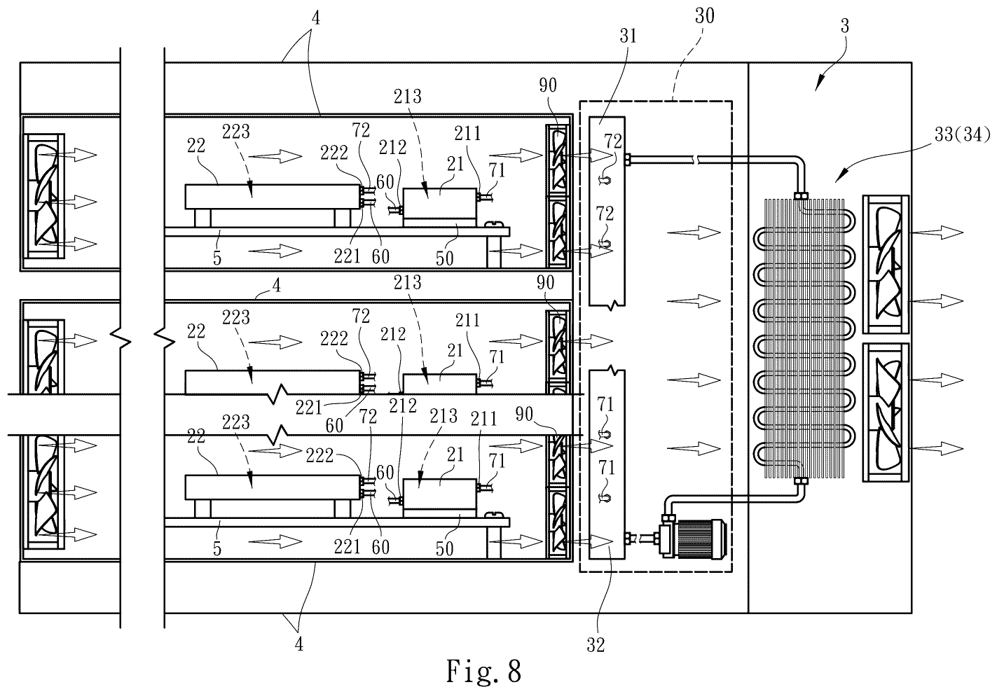

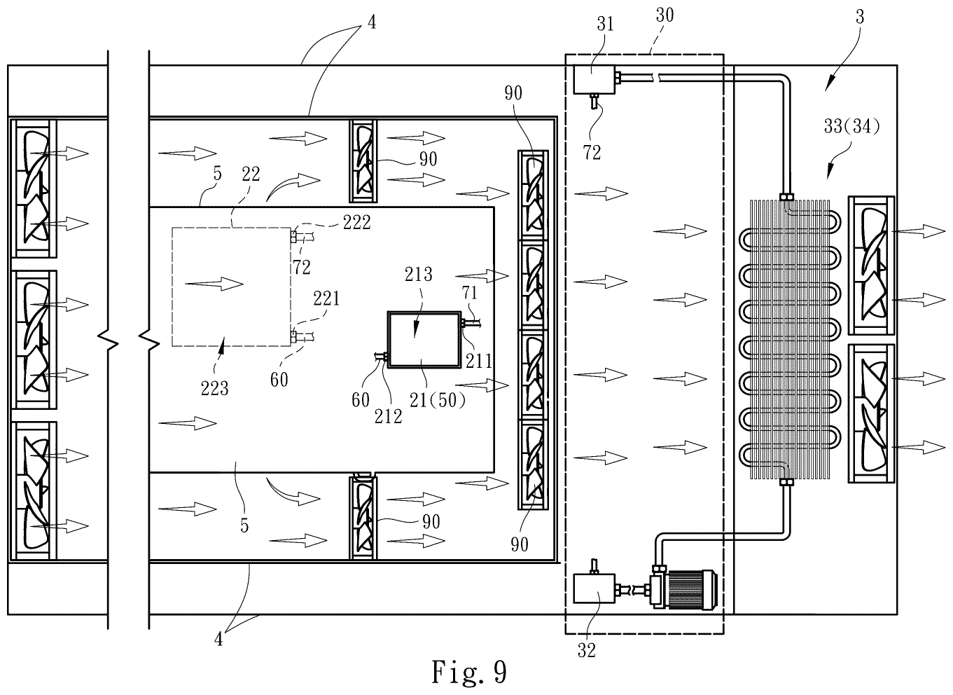

FIGS. 4 and 5 are top view and side view, respectively, showing an embodiment of the heat dissipation assembly of the present invention being applied to one single motherboard 5 that has a plurality of power heat sources 50 provided thereon; and FIGS. 6 to 9 show another embodiment of the heat dissipation assembly of the present invention being applied to one single chassis 4, which has a plurality of motherboards 5 mounted therein and each of the motherboards 5 has one single power heat source 50 mounted thereon. Please refer to FIGS. 4 to 9 at the same time. The water cooling radiator 22 is connected to the water block 21 via an internal connection pipe 60. The water cooling radiator 22 has an inlet 221 and an outlet 222, and internal defines at least one flow passage 223. The water outlet 212 of the water block 21 can be serially connected to the water inlet 211 of another water block 21 via a serial connection pipe 210, or connected to the inlet 221 of one water cooling radiator 22 via the internal connection pipe 60, such that the heat exchange space 213 in the water block 21 is communicable with the at least one flow passage 223 in the water cooling radiator 22, allowing a working fluid to flow between the water block 21 and the water cooling radiator 22. A plurality of water cooling radiators 22 may also be serially connected via one or more serial connection pipes 220 (as shown in FIGS. 4 and 5).

The water cooling radiator 22 is in the form of a thin plate characterized by small volume but large surface area, so that it is very suitable for mounting in a space located between the motherboard 5 and the chassis 4 that has a small height and a relatively large area and is parallel with the motherboard 5. For example, as shown in FIGS. 4 and 5, the water cooling radiator 22 is mounted to an underside of the motherboard 5, at where no other or only fewer electronic elements and no water block 21 are mounted; and the water cooling radiator 22 may be in contact with or not in contact with the motherboard 5 when being mounted thereto. Alternatively, the water cooling radiator 22 can be mounted in a space of the chassis 4 that is located above or adjacent to two lateral sides of and extending parallelly with the water block 21. In this way, a vertical (high) and narrow space existing between the chassis 4 and the motherboard 5 can also be well utilized to largely increase effective heat dissipation area in these space. There may be a plurality of water cooling radiators 22 being spaced from one another vertically, as shown in FIGS. 4 and 5, or being located on the same level and spaced from one another horizontally, so as to enable largely increased overall heat dissipation area in the chassis 4.

In the case of being applied to integrated electronic equipment having a plurality of system units, particularly as shown in FIGS. 4 to 9, the above described internal circulation heat dissipation assembly 2 is connected to the external forced cooling assembly 3 via a cooling water manifold assembly 70. The external forced cooling assembly 3 includes a coolant distribution unit (CDU) 30 and a heat-exchanger cooler connected to the CDU 30 via pipes. The heat-exchanger cooler can be at least one of an air heat-exchanger cooler 33 and a liquid heat-exchanger cooler 34. The CDU 30 may include an input distribution unit 31 and an output distribution unit 32. The external forced cooling assembly 3 enables a forced cooling operation to cool down a working fluid entering the external forced cooling assembly 3, and pumps the cooled working fluid into the chassis 4 again for cooling the power heat source 50.

The cooling water manifold assembly 70 includes a first pipe 71 and a second pipe 72. The first and the second pipe 71, 72 respectively have an end connected to the water inlet 211 of the water block 21 and the outlet 222 of the water cooling radiator 22; and another end connected to the pipes of the coolant distribution unit (CDU) 30. The working fluid flowing through the whole internal circulation heat dissipation assembly 2 and the external forced cooling assembly 3 undertakes the work of carrying heat to circulate in the whole system.

When the working fluid flows into the first pipe 71 and the water inlet 211 of the water block 21, it absorbs the working heat created by the power heat source 50 and is heated; the heated working fluid is output to and guided into the water cooling radiator 22. With the large heat dissipation area of the water cooling radiator 22, the working fluid preliminarily releases a part of the absorbed heat to cool down in a front stage, such that the working fluid circulates through the internal circulation heat dissipation assembly 2 has obviously dropped temperature. Then, the working fluid cooled down in the first stage is input to the external forced cooling assembly 3 via the second pipe 72 and subjected to a rear stage heat dissipation and cooling operation, so that the working fluid cools down fast and efficiently to increase a temperature difference (or hot level difference) between the working fluid and the power heat source 50. Thus, when the working fluid flows from the first pipe 71 into the water block 21 again, the heat accumulated in the power heat source 50 can be more efficiently carried away by the working fluid to effectively reduce the heat deposition in the power heat source 50, allowing the power heat source 50 to cool down effectively and quickly without forming deposited heat.

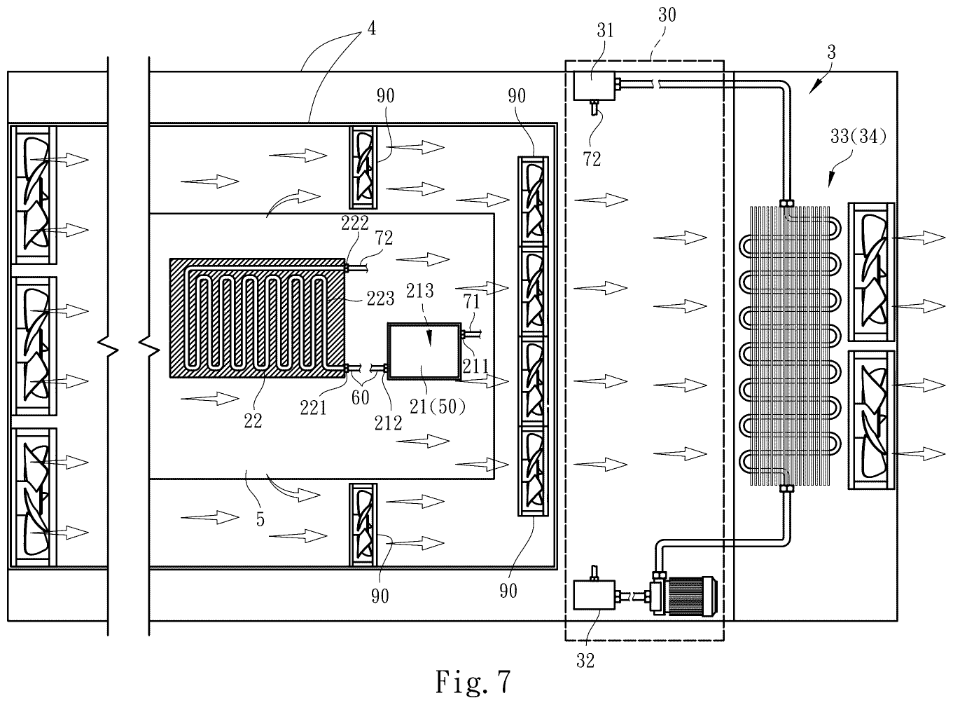

Please refer to FIGS. 7 to 9. In the event the water cooling radiators 22 have absorbed a large amount of heat created by the chassis 4 and can no longer remove further deposited heat from the chassis 4, it is still possible to result in high temperature in the chassis 4. Therefore, to effectively achieve the object of the present invention and solve the above problems, the heat dissipation assembly for electronic equipment according to the present invention further includes at least one enhanced pushing fan 90 provided in at least a middle section of the chassis 4 in the electronic equipment, so that hot air in the chassis 4 can flow in and be expelled from the chassis 4 at an increased speed to protect the chassis 4 against internal heat deposition when the water cooling radiators 22 dissipating heat at a high speed.

There may be one or more enhanced pushing fans 90 provided in the chassis 4. In the case a plurality of enhanced pushing fans 90 is used, it is better they are located separately on at least one of a middle and a rear space in the chassis 4, so that hot air in the chassis 4 can be fully dissipated to avoid locally high temperature in the chassis 4 due to heat deposition.

So long as the internal space of the chassis 4 is available, more enhanced pushing fans 90 can be properly mounted in the chassis 4 to enhance air circulating and flowing in the chassis 4 and hot air discharging from the chassis 4. In this way, it is able to effectively dissipate the heat accumulated in the chassis 4 and reduce the temperature of air surrounding the water cooling radiators 22. Therefore, the water cooling radiators 22 have effectively upgraded heat dissipation effect to also enhance the front stage heat dissipation and cooling effect.

In brief, the present invention includes one or more large-area water cooling radiators 22 provided between the conventional internal circulation heat dissipation assembly 2 and the external forced cooling assembly 3, so that the heat produced by the power heat sources 50 and absorbed by the working fluid in the water blocks 21 undergoes a front stage cooling at the water cooling radiators 22 and drops to a predetermined temperature preliminarily. And, the preliminarily cooled working fluid circulating through the internal circulation heat dissipation assembly 2 is transported to the external forced cooling assembly 3 and subjected to an forced cooling operation to be easily cooled down to a desired temperature. With these arrangements, the present invention is able to meet the requirement for further upgraded heat dissipation ability. Further, in the present invention, enhanced pushing fans 90 are mounted in the chassis 4 to not only guide and expel the hot air in the chassis 4 out of the chassis 4, but also reduce the temperature of air surrounding the water cooling radiators 22. With the enhanced pushing fans 90, the heat dissipation effect of the water cooling radiators 22 is further upgraded and the effect of front stage cooling operation obviously enables omission of costs for adding additional or new external forced cooling assemblies with higher power. Therefore, the present invention can largely upgrade the heat-exchange efficiency of the cooling system in the limited space while saving the power or energy that is otherwise consumed in the prior art by additional or new circulation cooling equipment.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A heat dissipation assembly for electronic equipment, comprising an internal circulation heat dissipation assembly (2) and an external forced cooling assembly (3) connected to the internal circulation heat dissipation assembly (2) to allow a working fluid to circulate between the two assemblies (2, 3); the internal circulation heat dissipation assembly (2) including at least one water block (21) mounted on a power heat source (50), and at least one water cooling radiator (22) connected to the at least one water block (21) via pipes; and the power heat source (50) being mounted on a motherboard (5) in a chassis (4) of the electronic equipment;
the water block (21) being correspondingly mounted on and in contact with the power heat source (50); and
the water cooling radiator (22) and the water block (21) being connected via pipes to allow the working fluid to circulate therebetween; the water cooling radiator (22) being mounted in a remaining space in the chassis (4), and the remaining space being located between the chassis (4) and the motherboard (5) and parallel with the motherboard (5); the working fluid in the water block (21) absorbing heat produced by the power heat source (50), and the working fluid having absorbed the heat and flowing into the water cooling radiator (22) undergoing a front stage heat dissipation to be cooled down preliminarily; and the working fluid entering the external forced cooling assembly (3) being subjected to a rear stage forced cooling through heat exchange to enhance a cooling efficiency of the working fluid and ensure the working fluid flowing back to the water block (21) has been sufficiently cooled to a desired low working temperature.

2. The heat dissipation assembly for electronic equipment as claimed in claim 1, further comprising a cooling water manifold assembly (70) consisting of a first pipe (71) and a second pipe (72); and wherein the water block (21) internally defines a heat exchange space (213) and has a water inlet (211) and a water outlet (212) communicable with the heat exchange space (213); and the water cooling radiator (22) internally defines a flow passage (223) and has an inlet (221) and an outlet (222); and the first pipe (71) being connected at an end to the water inlet (211) of the water block (21), and the second pipe (72) being connected at an end to the outlet (222) of the water cooling radiator (22); and the first and the second pipe (71, 72) being respectively connected at another end to the pipes of the external forced cooling assembly (3).

3. The heat dissipation assembly for electronic equipment as claimed in claim 2, wherein the water outlet (212) of the water block (21) is adapted to connect to one of the water inlet (211) of the water block (21) and the inlet (221) of the water cooling radiator (22).

4. The heat dissipation assembly for electronic equipment as claimed in claim 2, wherein the external forced cooling assembly (3) includes at least one coolant distribution unit (30) and a heat-exchanger cooler connected to the coolant distribution unit (30); and the coolant distribution unit (30) having an input distribution unit (31) and an output distribution unit (32) connected via pipes to the first pipe (71) and the second pipe (72), respectively.

5. The heat dissipation assembly for electronic equipment as claimed in claim 3, wherein the external forced cooling assembly (3) includes at least one coolant distribution unit (30) and a heat-exchanger cooler connected to the coolant distribution unit (30); and the coolant distribution unit (30) having an input distribution unit (31) and an output distribution unit (32) connected via pipes to the first pipe (71) and the second pipe (72), respectively.

6. The heat dissipation assembly for electronic equipment as claimed in claim 4, wherein the heat-exchanger cooler is selected from the group consisting of an air heat-exchanger cooler (33) and a liquid heat-exchanger cooler (34).

7. The heat dissipation assembly for electronic equipment as claimed in claim 5, wherein the heat-exchanger cooler is selected from the group consisting of an air heat-exchanger cooler (33) and a liquid heat-exchanger cooler (34).

8. The heat dissipation assembly for electronic equipment as claimed in claim 1, wherein there is a plurality of water cooling radiators (22) included in the internal circulation heat dissipation assembly (2); and the water cooling radiators (22) being located above or below the motherboard (5) to be parallelly spaces from but communicable with each other.

9. The heat dissipation assembly for electronic equipment as claimed in claim 2, wherein there is a plurality of water cooling radiators (22) included in the internal circulation heat dissipation assembly (2); and the water cooling radiators (22) being located above or below the motherboard (5) to be parallelly spaces from but communicable with each other.

10. The heat dissipation assembly for electronic equipment as claimed in claim 3, wherein there is a plurality of water cooling radiators (22) included in the internal circulation heat dissipation assembly (2); and the water cooling radiators (22) being located above or below the motherboard (5) to be parallelly spaces from but communicable with each other.

11. The heat dissipation assembly for electronic equipment as claimed in claim 4, wherein there is a plurality of water cooling radiators (22) included in the internal circulation heat dissipation assembly (2); and the water cooling radiators (22) being located above or below the motherboard (5) to be parallelly spaced from but communicable with each other.

12. The heat dissipation assembly for electronic equipment as claimed in claim 6, wherein there is a plurality of water cooling radiators (22) included in the internal circulation heat dissipation assembly (2); and the water cooling radiators (22) being located above or below the motherboard (5) to be parallelly spaced from but communicable with each other.

13. The heat dissipation assembly for electronic equipment as claimed in claim 1, wherein the chassis (4) is internally provided in at least a middle area with at least one enhanced pushing fan (90).

14. The heat dissipation assembly for electronic equipment as claimed in claim 2, wherein the chassis (4) is internally provided in at least a middle area with at least one enhanced pushing fan (90).

15. The heat dissipation assembly for electronic equipment as claimed in claim 3, wherein the chassis (4) is internally provided in at least a middle area with at least one enhanced pushing fan (90).

16. The heat dissipation assembly for electronic equipment as claimed in claim 4, wherein the chassis (4) is internally provided in at least a middle area with at least one enhanced pushing fan (90).

17. The heat dissipation assembly for electronic equipment as claimed in claim 5, wherein the chassis (4) is internally provided in at least a middle area with at least one enhanced pushing fan (90).

18. The heat dissipation assembly for electronic equipment as claimed in claim 6, wherein the chassis (4) is internally provided in at least a middle area with at least one enhanced pushing fan (90).

19. The heat dissipation assembly for electronic equipment as claimed in claim 8, wherein the chassis (4) is internally provided in at least a middle area with at least one enhanced pushing fan (90).

20. The heat dissipation assembly for electronic equipment as claimed in claim 9, wherein the chassis (4) is internally provided in at least a middle area with at least one enhanced pushing fan (90).

21. The heat dissipation assembly for electronic equipment as claimed in claim 11, wherein the chassis (4) is internally provided in at least a middle area with at least one enhanced pushing fan (90).

22. The heat dissipation assembly for electronic equipment as claimed in claim 12, wherein the chassis (4) is internally provided in at least a middle area with at least one enhanced pushing fan (90).
